(19) United States
(12) Patent Application Publication
(10) Pub. No.: US 2025/0167533 A1
(43) Pub. Date: May 22, 2025

(54) BIODEGRADABLE HARDWARE

(71) Applicant: LIBERTY HARDWARE MFG. CORP., Winston-Salem, NC (US)

(72) Inventors: James Leroy DANIELS, Stokesdale, NC (US); Earl David FORREST, Asheboro, NC (US)

(73) Assignee: LIBERTY HARDWARE MFG. CORP., Winston-Salem, NC (US)

(21) Appl. No.: 19/031,822

(22) Filed: Jan. 18, 2025

Related U.S. Application Data
(62) Division of application No. 18/486,691, filed on Oct. 13, 2023.
Application No. 18/486,691 is a continuation of application No. 15/638,978, filed on Jun. 30, 2017, now abandoned.

(51) Int. Cl. H02G 3/08; H01B 3/38; H01R 13/52; H01R 25/00; H02G 3/04; H02G 3/12; H05K 5/02

(52) U.S. Cl. CPC H02G 3/088; H01B 3/38; H01R 13/5213; H01R 25/006; H02G 3/12; H05K 5/0221; H02G 3/0412

(57) ABSTRACT

A biodegradable electrical enclosure is provided and has a plate having a rear mounting surface and a front appearance surface. An aperture extends through the plate for receiving an electrical component. The plate is formed of a natural fiber thermoset composite (NFTC) having at least one fire-retardant additive.

### CROSS-REFERENCE TO RELATED APPLICATIONS

This application is a division of U.S. application Ser. No. 18/486,691 filed Oct. 13, 2023, which is a continuation of U.S. application Ser. No. 15/638,978 filed Jun. 30, 2017, now abandoned, the disclosures of which are hereby incorporated in their entirety by reference herein.

### TECHNICAL FIELD

The present application relates to hardware made of biodegradable material.

### BACKGROUND

Hardware, such as electrical enclosures, are typically formed of flame-resistant polymers or metal to meet design and function requirements. Hardware, such as hooks and knobs, are also made of metal. However, after disposed of or replaced, the hardware made of polymeric or metal materials will take many generations before initial decomposition occurs.

### SUMMARY

According to one embodiment, a biodegradable electrical enclosure is provided and has a plate having a rear mounting surface and a front appearance surface. An aperture extends through the plate for receiving an electrical component. The plate is formed of a natural fiber thermoset composite (NFTC) having at least one fire-retardant additive.

According to another embodiment, the fire-retardant additive has melamine at a quantity to meet industry safety test UL514D.

According to another embodiment, the NFTC has melamine in a range of 20 to 40 percent by volume.

According to another embodiment, the fire-retardant additive has melamine-urea-formaldehyde (MUF).

According to another embodiment, the fire-retardant additive also has at least one of aluminum hydroxide, magnesium hydroxide and corn starch.

According to another embodiment, a depth distance from the front appearance surface to the rear mounting surface is less than six millimeters.

According to another embodiment, the NFTC includes bamboo. According to another embodiment, the natural-fiber bamboo is at least 25 percent of the NFTC by volume.

According to another embodiment, a thickness between the front appearance surface and an inside surface is in a range of two to four millimeters.

According to another embodiment, the front appearance surface has a high-relief design.

According to another embodiment, the high-relief design extends beyond a base surface by a relief distance in the range of one-half to three millimeters.

According to another embodiment, the electrical enclosure does not have a secondary grounding plate.

According to another embodiment, the plate is a wall plate and the aperture is sized as at least one of a switch opening and an outlet opening.

According to one embodiment, a hardware assembly is provided having a biodegradable hardware component formed of a natural fiber thermoset composite (NFTC). A metallic insert is coupled to the biodegradable hardware component. A fastener engages the metallic insert for mounting the biodegradable hardware component.

According to another embodiment, the biodegradable hardware component is a hook.

According to another embodiment, the metallic insert comprises a flange along a surface of the biodegradable hardware component. The metallic insert extends through a recessed opening in the biodegradable hardware component to a mounting surface on the biodegradable hardware component. The metallic insert having a threaded aperture to engage the fastener.

According to another embodiment, an accent part is connected to a metallic final, wherein the fastener extends through the accent part and engages the metallic final.

According to another embodiment, the biodegradable hardware component is a base of a knob.

According to another embodiment, the biodegradable hardware component has a protrusion. The metallic insert is cylindrical and the metallic insert retains the protrusion at a first end, and has a threaded aperture to engage the fastener at a second end.

According to another embodiment, the protrusion has an angled dovetail shape and the metallic insert has a corresponding dovetail shaped groove.

### BRIEF DESCRIPTION OF THE DRAWINGS

FIG. 1 is a front view of a biodegradable hardware component according to one embodiment.

FIG. 2 is a section view of the biodegradable hardware component of FIG. 1.

FIG. 3 is a detailed section view of a portion of the biodegradable hardware component of FIG. 1.

FIG. 4 is a front view of a biodegradable hardware component according to another embodiment.

FIG. 5 is a front view of a biodegradable hardware component according to another embodiment.

FIG. 6 is an exploded view of a hardware assembly according to another embodiment.

FIG. 7 is a section view of a hardware assembly according to another embodiment.

FIG. 8 is an exploded view of the hardware assembly of FIG. 7.

FIG. 9 is a front view of a hardware assembly according to another embodiment.

FIG. 10 is a section view of the hardware assembly of FIG. 9.

FIG. 11 is a section view of a hardware assembly according to another embodiment.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

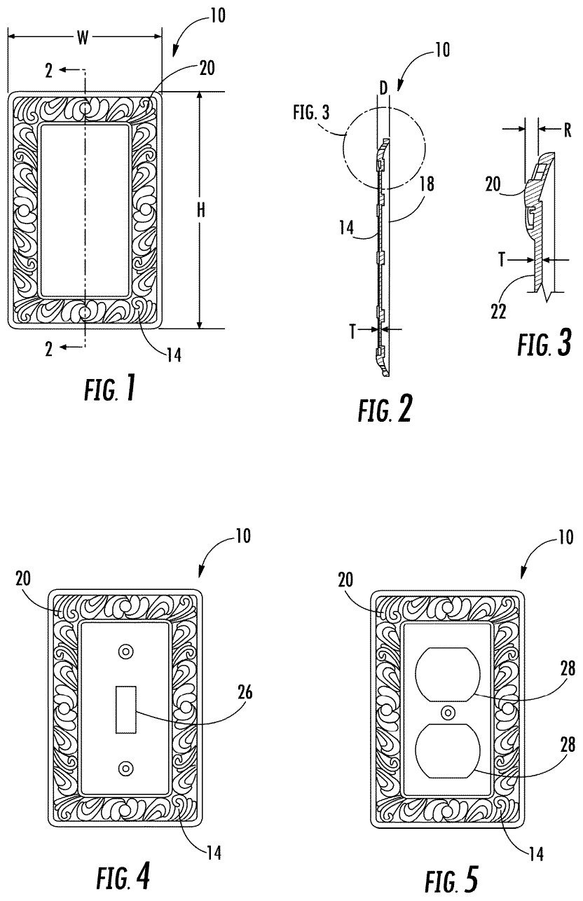

FIG. 1 illustrates one example of an electrical enclosure. The wall plate 10 is intended to cover electrical switches, outlets wall timers and the like in residential homes and offices. Generally, these electrical enclosures are more commonly made from flame-retardant polymeric materials and are subject to industry safety standards such as UL514D “Cover Plates for Flush Mounted Wiring Devices.” Alternatively, wall plates are fabricated from sheet steel. To meet retail price targets both frame-retardant polymers and steel have inherent design constrictions. It is not possible to make high-relief wall plate designs with cost-effective flame-retardant polymers. Due to potential flame propagation across high relief it necessary for a higher anti-flame rating at significantly higher raw material cost. Similarly, high relief designs can be created in steel stampings, however due to the 0.8 mm minimum thickness requirement, fine details are not possible due to the minimum bend radius to thickness relationship. A more attractive design is commonly achieved with high-relief and well defined decorative details in a zinc diecast components as an alternative to polymers or sheet metal, but at several times the costs. Wall plates with high-relief may also be formed of medium density fiberboard (MDF) or natural wood. With MDF or natural wood, the wall plate is formed of two pieces and the front facia plate is machined from and then a secondary component is generally made from a pre-galvanized steel to serve as a grounding plate. Due to the large number of machining steps in the facia component and the need for a secondary component, a wall plate assembly formed of MDF or natural wood is also expensive to manufacture.

The electrical enclosure illustrated in FIG. 1 is formed compression moldable natural fiber thermoset composite (NFTC) material to create the wall plate 10 or sixth side of an electrical enclosure. The electrical enclosure of the present disclosure eliminates expensive flame retardant polymeric materials and utilizes less costly compression die tooling when compared to injection molded thermoplastics and tooling. The NFTC has flame-suppression characteristics, and may have cost-effective flame-retardant components added. Compression molding processes also allow for high relief and well defined decorative details without the need for die casting zinc or more costly flame retardant polymers.

According to one embodiment, the NFTC flame-retardant compound contains equal parts of bamboo powder or bamboo fiber and melamine (C₃H₆N₆) as well cellulose pulp, aluminum hydroxide (Al(OH)₃) and corn starch. Dyes or colorants can also be added to the compound to change the color of the product without the need for secondary operations such as paint, glazes or plating. Alternatively, small concentrations of rice husk can be added to the compound to create visual interest through naturally occurring contrast in color against the predominately white powder compound. The preferred embodiment reduces the products carbon footprint over conventional materials such as MDF or natural wood while also eliminating the need for a metal shield required by industry standards. In addition, this present application utilizes bamboo fiber, cellulose and corn starch in sufficient concentrations to allow the material to biodegrade when buried in time scales that can be measured in months. By comparison, most common polymeric materials will take many generations before initial decomposition occurs.

According to one embodiment, the NFTC chemical composition includes:
30% Bamboo Fiber (Powder)
30% Melamine C₃H₆N₆ (CAS: 108-78-1)
20% Cellulose Pulp (C₆H₁₀O₅)n (CAS: 9004-34-6)
10% Aluminum Hydroxide Al(OH)₃ (CAS: 21645-51-2)
08% Corn Starch (C₆H₁₀O₅)n (CAS: 9005-25-8)
2% Other

This NFTC composition includes several fire-retardant components. For example, melamine contains 66% nitrogen by mass. When melamine is combined into a resin it exhibits fire retardant properties due to the release of nitrogen gas when burned or charred. Aluminum hydroxide is commonly used as a fire-retardant filler for polymer applications. When aluminum hydroxide is heated to about 180° C. (356° F.), it decomposes and absorbs a considerable amount of heat in the process and giving off water vapor. Corn starch, or corn-starch water based enhancer may also be used in flame suppression. Other flame-retardant components may also be used. As an example, magnesium hydroxide also has flame retardant properties and could be substituted for aluminum hydroxide (Al(OH)₃.) However, magnesium hydroxide decomposes at a much higher temperature of about 332° C. (630° F.). Similarly, Melamine C₃H₆N₆ could be replaced at least in part with urea-formaldehyde forming a resin blend known as melamine-urea-formaldehyde (MUF).

The NFTC composition is fire-retardant to meet industry safety standards. For example, the wall plate formed of NFTC will not ignite within fifteen seconds after the application of the hot wire ignition test. The wall plate formed of NFTC will not combustion after application of a flame test for more than one-minute. The wall plate formed of NFTC in the vicinity of the test flame was not destroyed such that the integrity of the electrical enclosure was unaffected and there was no visible flame on the surface opposite to the surface where the test flame was applied and an opening through the wall plate.

The process of manufacturing a wall plate using NFTC resin uses both heat and pressure. The thermoset resin including fine particulate power of natural fiber is poured into a compression mold die. The die is pre-heated, typically to no more than 160° C. and then the die is closed and pressure is applied. Molding pressure may range from 65 MPa (9,500 psi) to 75 MPa (10,500 psi). During the process the die may be released for a short duration to allow the escape of water vapor and then closing the die for a final cure dwell period. Although the temperature can be greater than 160° C., the temperature should not be raised above the decomposition temperature any component, such as above 180° C. when using aluminum hydroxide. Also, at temperatures above 160° C., carbonization results in is material discoloration becomes increasingly evident.

During the heating process the resins liquefy and combine with the natural fiber powder, such a bamboo. As the resin is heated, both lignin and cellulose in the bamboo powder transfer into the liquid phase which further contributes to a uniform adhesion of all components within the formula. Once the molded part has cured, the shape cannot be reversed and is considered stable from a heat-deformation perspective. The surfaces of the finished part are typically smooth and uniform and may exhibit a high gloss level on polished tooling dies.

When tested under international testing standards, the electrical enclosure 10 molded of NFTC may exhibit the following physical mechanical approximate properties:
Material Density: 1.412 g/cm³
Flexural Modulus: 1,381 (ksi) ASTM D790
Flexural Strain at Break 1.17(%) ASTM D790
Flexural Stress at Break 15,300 (psi) ASTM D790
Poisson's Ratio 0.336 (in/in) ASTM D638
Tensile Modulus 1,370 (ksi) ASTM D638

The wall plate 10 must sufficiently cover the electrical box and meet the National Electrical Manufacturers Association (NEMA) standards, while minimizing material usage. For example, the single gang wall plate 10 in FIG. 1 may have an overall height H not less than 123.70 mm and an overall width W not less than 79.25 mm. Ideally, the ratio between the long and short sides of the single gang wall plate will be between 1.40 and 1.70. Multi gang units would then be larger than the single gang by incrementing the width W by 46.04 mm.

The wall plate 10 has a front appearance surface 14. As shown in the section view in FIG. 2, the wall plate 10 may have a wall thickness T of not less than 1.2 mm. In another embodiment, the wall thickness may be in the range of 2.0 mm to 4.0 mm.

The wall plate 10 also has a rear mounting surface 18 that is adapted to abut the wall or mounting surface. With the molding process and NFTC material, the wall plate 10 is able to achieve a low-profile between the mounting surface and the front appearance surface 14 that can typically only be achieved with zinc. The distance or depth D between the front appearance surface 14 is generally six millimeters or less.

As shown in FIG. 1, the wall plate 10 may have a high relief design 20. The high relief details 20 are raised from the base plane or smooth surface. As shown in in more detail in FIG. 3, the wall plate 10 the high-relief design extends beyond a base appearance surface 22 by a relief distance R in the range of one to three millimeters. The relief distance may be any distance based on the design and space provided.

The wall plate 10 has an aperture 26 through which an electrical component extends. For example, FIG. 4 illustrates a wall plate 10 having a switch aperture 26 sized to receive a switch. In FIG. 5, the wall plate has a pair outlet apertures 28 each sized to receive an electric plug outlet. Of course, other shaped electrical apertures may be provided depending on the application.

While the electrical enclosure is illustrated as a wall plate, the electrical enclosures can take on many forms such as the base of a towel bar which might be illuminated, as one example. The electrical enclosure may include any component that receives, encloses, or houses an electrical component.

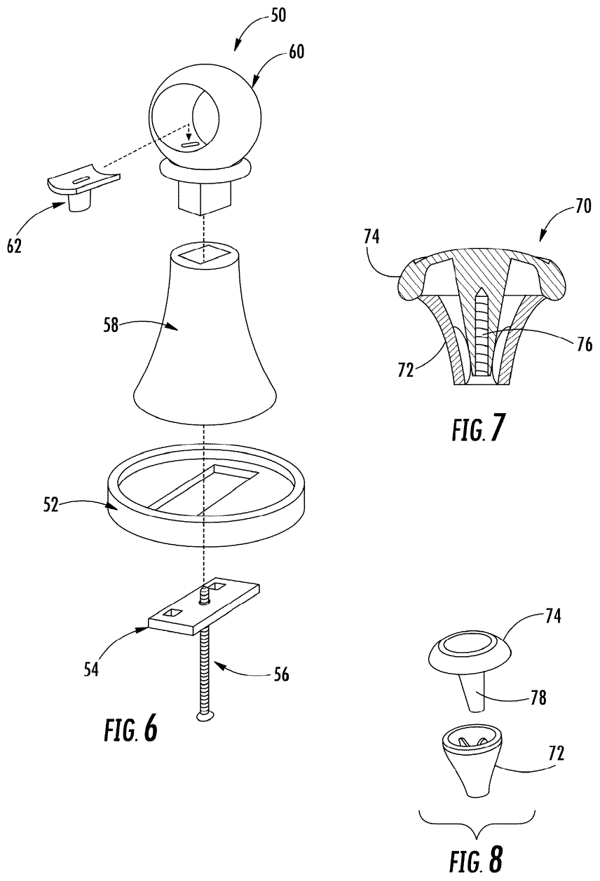

FIGS. 6-12 illustrate biodegradable hardware formed of NFTC according to another embodiment. The NFTC base formula could be changed, eliminating the Aluminum Hydroxide Al(OH)₃ altogether to create other products which do not have a need for elevated flame resistance.

For example, FIG. 6 illustrates the exploded view of a towel bar post assembly 50 using NFTC. The post assembly 50 has a base 52 that mounts to mounting surface, such as a cabinet door or wall, for example. The base 52 may be formed of NFTC. Since NFTC is stronger in compression than tension, the base 52 may include a mounting aperture for a metal insert 54 that receives the fastener 56. The post assembly 50 may also include an accent part 58 formed of NFTC. The accent part 58 is positioned between the base 52 and the final 60. The final 60 may be formed of metal or polymer, or any suitable material and have a threaded opening to receive the fastener 56. Alternatively, the final 60 may also be formed of NFTC. When the final is formed of NFTC, it includes a metal insert 62 to receive the fastener. The metal insert 62 may be formed of zinc or stamped steel, or any suitable insert material to receive the fastener 56 and secure the post assembly 50 to a mounting surface.

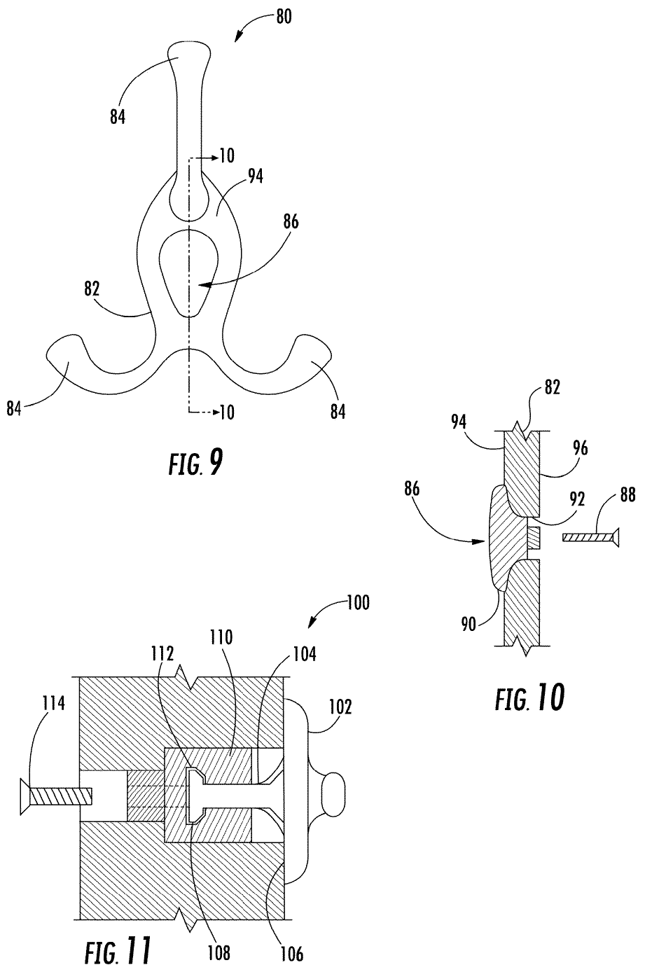

FIG. 7-8 illustrate a knob assembly 70 according to another embodiment. The knob assembly 70 includes a base 72 adapted for mounting to a mounting surface. The base 72 may be formed of NFTC. A cap 74 attached to the base 72. The cap 74 may be formed of zinc or any suitable material for receiving the fastener 76. The cap 74 has a stem 78 with a threaded opening that extends into the base 72 and engages the fastener 76 and secure the knob assembly 70 to a mounting surface.

FIGS. 9-10 illustrate hook 80 that may also be formed of NFTC that does not require Aluminum Hydroxide Al(OH)₃ since the hook 80 does not have a need for elevated flame resistance. The hook 80 is a two-piece design where the hook body 82 is made of NFTC. The hook body 80 has three separate hook extensions 84, but any number of hook extensions may be used, depending on the application. The hook 80 has a center metal insert 86 that receives the fastener 88. The metal insert 86 may have a flange 90 to retain the insert 86 in recessed opening 92 on the hook body 82. The insert 86 may be formed of zinc or any suitable material

FIGS. 9-10 illustrate the insert 86 mounted from the front, the flange 90 is retained adjacent the front surface 94 of the hook body 82. The insert 86 extends through the recessed opening 92 to a mounting surface 96. The metallic insert 86 has a threaded aperture adjacent the mounting surface 96 to engage the fastener. In another embodiment, a rear-mounted insert may be used and the fastener may engage a threaded opening adjacent the front surface.

FIG. 11 illustrates a hardware assembly 100 partially formed of NFTC according to another embodiment. The hook 102 is made of NFTC. The hook 102 has a stem 104 extending from the rear mounting surface 106. The distal end of the stem 104 includes protrusion 108. The protrusion 108 may be a dovetail shape, dog-bone shape or another suitable protrusion configuration. The protrusion 108 engages a metal insert block 110. The block 110 has a groove 112 to retain the protrusion 108 and a threaded opening that extends into the block 110 opposite the groove 112 and engages a fastener 114 to secure the mounting surface 104 of the hook 102 to a hook rail, for example.

Other mounting hardware may be formed of NFTC and have a for glue feature interface, as described in U.S. Pat. No. 8,060,988 by Liberty Hardware Manufacturing Corp, the disclosure of which is hereby incorporated by reference.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A hardware assembly comprising:
a biodegradable hardware component formed of a natural fiber thermoset composite (NFTC);
a metallic insert coupled to the biodegradable hardware component; and
a fastener engaging the metallic insert for mounting the biodegradable hardware component.

2. The hardware assembly of claim 1 wherein the biodegradable hardware component comprises a hook.

3. The hardware assembly of claim 1 wherein the metallic insert comprises a flange along a surface of the biodegradable hardware component, and the metallic insert extends through a recessed opening in the biodegradable hardware component to a mounting surface on the biodegradable hardware component, the metallic insert having a threaded aperture to engage the fastener.

4. The hardware assembly of claim 1 wherein the biodegradable hardware component comprises an accent part connected to a metallic final, wherein the fastener extends through the accent part and engages the metallic final.

5. The hardware assembly of claim 2 wherein the biodegradable hardware component comprises a base of a knob.

6. The hardware assembly of claim 1 wherein the biodegradable hardware component comprises a protrusion, and the metallic insert is cylindrical and retains the protrusion at a first end, and has a threaded aperture to engage the fastener at a second end.

7. The hardware assembly of claim 6 wherein the protrusion has an angled dovetail shape and the metallic insert has a corresponding dovetail shaped groove.
